(19) United States
(12) Patent Application Publication
(10) Pub. No.: US 2012/0240490 A1
(43) Pub. Date: Sep. 27, 2012

(54) ROOF MOUNTED PHOTOVOLTAIC SYSTEM WITH ACCESSIBLE PANEL ELECTRONICS

(76) Inventor: Ronald J. Gangemi, Grass Valley, CA (US)

(21) Appl. No.: 13/429,881

(22) Filed: Mar. 26, 2012

Related U.S. Application Data
(60) Provisional application No. 61/465,859, filed on Mar. 25, 2011.

(51) Int. Cl. E04D 13/18; E04B 1/38; E04H 14/00; H01L 31/18

(52) U.S. Cl. 52/173.3; 29/890.033; 248/237; 52/173.1

(57) ABSTRACT

A support system for photovoltaic cells upon a roof. A cell support structure is provided beneath each cell, such as in the form of a pair of brackets to form a photovoltaic panel. The panels overlap partially to function somewhat as shingles, to shed water off of the roof. A lower side wall of each photovoltaic panel has at least one port therein to selectively access a space beneath the photovoltaic cell. Photovoltaic cell electronics, such as an inverter for one or a series of cells. A door is provided in one embodiment which selectively covers the port and acts as a support for the photovoltaic cell electronics.

### CROSS-REFERENCE TO RELATED APPLICATIONS

This application claims benefit under Title 35, United States Code §119(e) of U.S. Provisional Application No. 61/465,859 filed on Mar. 25, 2011.

### FIELD OF THE INVENTION

The following invention relates to mounting systems for mounting photovoltaic cells on roofs of buildings. More particularly, this invention relates to mounting brackets and bracketless systems for supporting photovoltaic cells upon roofs in a manner which has a low profile and blends in with adjacent shingles while also facilitating access to panel electronics beneath the photovoltaic cells.

### BACKGROUND OF THE INVENTION

Photovoltaic cells have enjoyed increasing popularity over time as various different technical hurdles associated with the use of photovoltaic cells have been overcome. Photovoltaic cells are generally solid state devices formed of various materials (often silicon) which generate electric current when exposed to photonic radiation, such as solar radiation.

One form of photovoltaic cell is configured so that it can rest upon a bracket which is particularly configured to be mounted to the shingles on a roof or directly upon the roof and have perimeter edges thereof blend into the roofing structure. Such a system is described in Published Patent Application No. 2007/0042683, and is by the same inventor of this application. This published application is incorporated herein by reference in its entirety. The system of that application is particularly configured for relatively thick concrete tile type roofs. In contrast, composition roofs are quite thin, as well as certain tile roofs, such as slate roofs which have relatively thin shingles. Accordingly, a need exists for a lower profile mounting bracket for a photovoltaic cell assembly. Also, with such a lower profile technical challenges are presented such as how to keep the bracket and cells below temperatures at which damage can occur, and how to secure the bracket and cells to the roof sufficient to resist high wind loads.

Photovoltaic cells must operate effectively in an extreme thermal environment. The brackets supporting the cells must similarly endure this extreme environment. Not only does the temperature do damage to the materials forming the bracket, but also thermal forces cause thermal expansion which can lead to distortion or breakage of the cells, or loosening of the mounting system provided by the brackets. As brackets for photovoltaic cells become thinner, the opportunity to cool by natural convection beneath the bracket and above the roof is diminished. Especially when it is desirable to have the photovoltaic cells blend into the adjacent shingles, such blending tends to block natural convection air circulation cooling, leading to degraded performance.

In addition to thermal issues, photovoltaic panels benefit from being able to withstand the wind loads expected by local building codes. Such wind loads can be quite extreme in some environments, particularly those which periodically experience hurricanes or other extreme weather phenomena.

While separate photovoltaic panels can be coupled together in series or parallel forming a direct current circuit that feeds one or more inverters separate from the panels themselves, another option is to have an inverter associated with each panel or associated with a small subset of panels and to mount the inverter beneath the panels directly on the roof. Inverters known as micro-inverters or nano-inverters can convert relatively small amperage direct current and relatively low power direct current solar cell energy into alternating current that can then be delivered to the power grid or beneficially utilized by AC current power devices within a residence or other structure. However, as the inclusion of such inverters with panels on the roof is implemented, the panel system itself becomes more complex and potentially in need of more frequent service. Accordingly, a need exists for a photovoltaic cell rooftop mounting system where inverters and other electronics beneath the cells of the panels can be accessed for such maintenance, without requiring disassembly of the overall system and maintaining panel performance as a roofing material and as a power generation system.

### SUMMARY OF THE INVENTION

With this invention, a roof mounting bracket is provided for a photovoltaic power generation system that is particularly configured to allow assemblies of photovoltaic cells to be easily and securely mounted to roofs which have a thin roofing material such as composition roof shingles, slate shingles or other thin planar shingles. The mounting bracket and associated photovoltaic cells are relatively thin and are configured to be sealed in a watertight fashion so that the brackets and assemblies of cells can act effectively as shingles, while also accommodating natural convection air cooling of the brackets and panels to prevent excessive heat from building up and damaging the brackets or panels.

In particular, a standardized configuration bracket is provided which has an upper side generally defining a mounting portion which can be secured to an underlying roof. A lower side opposite the upper side forming the mounting portion is configured to overlap the mounting portion of the next lower bracket in a series of vertically spaced brackets extending down the slope of the roof. A cell support structure is provided between the mounting portion and the lower side. This cell support structure can support a plurality of photovoltaic cells and associated layers formed together in a cell stack assembly which rests upon the cell support structure and is secured to the cell support structure. This photovoltaic cell stack assembly is preferably twice as wide as the bracket so that two similarly formed brackets are placed adjacent each other and laterally spaced from each other to support a single photovoltaic cell stack assembly, and define a single “panel.” The joint between the two brackets acts as an expansion joint for the panel.

Such panels can each be fitted with a single J-box which receives electric power from the various cells within the photovoltaic cell stack assembly. This J-box can then be coupled to leads of J-boxes of adjacent panels in series. Each series string of panels can also be connected to a combiner box, an inverter and a sub-panel for effective utilization of the electric power generated by the panels.

The brackets have an air circulation system that allows air to be routed by natural convection beneath the brackets. A lowermost bracket of a series of vertically spaced brackets has an end piece fitted under a lower side thereof to hold up the lower side of the lowermost bracket (because it is not resting upon an upper side of a next lower bracket) to allow air to enter beneath the lowermost bracket. Ribs forming an underside of each bracket have various different passages or gaps therein to allow airflow through the end piece and beneath each bracket and then beneath the next higher bracket up in the series, until the air by natural convection escapes out an upper side of an uppermost bracket.

Edge flashing is provided to keep water from migrating around lateral sides of the brackets and the panels, especially at edges of an overall system of multiple panels. This flashing has one side that fits beneath shingles upon the roof adjacent a perimeter of the system. Wind clips are provided on each bracket which interlock with adjacent and lower brackets so that the brackets are somewhat interlocked together and resist wind loads acting upon the brackets.

In one form of the invention, rather than supplying brackets underneath the photovoltaic panels, the panels can be directly placed upon the roof without the brackets. In such an arrangement, some form of spacer, and typically elongate stringers, are oriented upon the roof and beneath a lower surface of the panels. These stringers preferably extend vertically on the roof and define airflow pathways between the stringers, with the panels resting upon the stringers. Adjacent panels spaced vertically from each other are preferably arranged overlapping slightly, so that water incident upon the surface of one photovoltaic panel falls to a lower edge of the panel and then on to a next lower panel, in cascading fashion over sequential panels, such that the panels themselves shed water incident upon the roof.

Bottom vents can be provided between the stringers to support a lower edge of a lowermost photovoltaic panel. A top vent can be provided overlying an upper edge of an uppermost panel, such that water incident upon the roof above the overall photovoltaic power generation system is kept from migrating beneath the panels, but rather is caused to flow over the upper surface of the panels. Lateral edge flashing is also provided to establish a water barrier along lateral edges of the array of panels.

Each panel preferably includes trim around a perimeter thereof. This trim facilitates interlocking of adjacent panels both when vertically spaced and laterally spaced. This trim can also be configured to allow for direct attachment to the roof so that portions of the panels which are not coupled to adjacent panels can be secured to the roof to keep the overall system securely in place upon the roof, not only to support gravity loads but also wind loads and other loads encountered in the environment.

In one embodiment each panel can have its own inverter or a small subset of panels can have their own inverter with this inverter converting the direct current generated by the cells into alternating current before adding the power from the single cell or small subset of cells to other panel's power outputs. Such micro-inverters or nano-inverters (and/or other photovoltaic cell electronics) would typically be provided beneath the cells of the panel and within a space in the cell support structure. In this embodiment, a port is provided within a bottom trim piece at a lower side wall of each panel, such as in the bottom rail of each bracket. This port is preferably generally rectangular and preferably one or two ports are provided on each panel within this bottom trim. A door is provided which can slide into and out of this port (along arrow D of FIGS. 28 and 29).

This door preferably includes a tray portion which is generally planar and a face portion which is perpendicular to the tray portion. The face portion is similar in size to the port, but preferably slightly larger and has a perimeter thereof which is configured to seal with the lower side wall. In this way, when the door is closed and the tray is entirely beneath the panel, the face abuts the lower side wall and seals the lower side wall substantially closed.

An inverter or other electronics associated with the panel, such as a junction box or other interconnection wiring can be mounted directly to an underside of the tray, or can otherwise be provided on a separate drawer or other structure which can be pulled out or directly accessed through the port. Sufficient slack is associated with wiring coupled to the electronics so that if electronics such as a micro-inverter or a nano-inverter are mounted to an underside of the tray, when the door is pulled out (along a direction opposite arrow D) the wiring can give up sufficient slack to allow the inverter to be accessed without disconnecting any of the wiring. In this way, an inverter or other wiring can be replaced, repaired or inspected through this port by opening of this door.

By providing each cell support structure of each panel with a pair of such ports, one along a lateral edge and one near a center portion, a variety of locations are available for positioning of the inverters depending on the arrangement of the array of panels on the roof. With such a door, the panels can remain affixed to adjacent panels and to the roof and the inverter or other electronic equipment beneath the panel can be accessed and inspected. Such a configuration enhances the reliability with which the panels can function as roofing material. This system avoids impairing the ability of the panels, once properly situated, to shed water off of the roof, or from being moved to an inappropriate position (such as to inspect wiring beneath the panel), potentially resulting in water penetration.

### OBJECTS OF THE INVENTION

Accordingly, a primary object of the present invention is to provide a system for generating power directly from sunlight that is mountable on a roof having thin shingles thereon, without compromising the performance of the roof or the performance of the power generation system.

Another object of the present invention is to provide a photovoltaic power generation system which can be mounted on a roof or other support structure and which is cooled by natural convection and secured in place to prevent displacement thereof.

Another object of the present invention is to provide a roof mounted photovoltaic power generation system which is easy to mount upon a roof of a structure.

Another object of the present invention is to provide a photovoltaic power generation system which includes multiple mounting brackets each of a similar construction to simplify construction of the overall system.

Another object of the present invention is to provide a roofing system which effectively keeps water from coming in contact with structural portions of the roof and which also is configured to convert solar radiation into electric power.

Another object of the present invention is to provide a power generation system which effectively utilizes the space available on the roof of a building as a source of solar power generation.

Another object of the present invention is to provide a method for interlocking solar panels on a roof that allows the panels to be easily mounted upon the roof and resist displacement due to wind loads thereon.

Another object of the present invention is to provide a roof mounting bracket for photovoltaic power generation system which can expand and contract with temperature changes without damaging the system.

Another object of the present invention is to provide a photovoltaic panel which can be easily connected to adjacent panels and an electric subsystem for conditioning the power and delivering the power for beneficial use.

Another object of the present invention is to provide a method and system for providing access to electronics and other cell equipment beneath the panel, without requiring panel dis-installation for service, inspection and/or repair.

Other further objects of the present invention will become apparent from a careful reading of the included drawing figures, the claims and detailed description of the invention.

### BRIEF DESCRIPTION OF THE DRAWING FIGURES

FIG. 1 is a top perspective view of a single bracket of the roof mounted photovoltaic power generation system of this invention.

FIG. 2 is a bottom perspective view of that which is shown in FIG. 1.

FIG. 3 is a top perspective view of a pair of mounting brackets joined together and ready to receive a photovoltaic cell stack assembly thereon with an expansion joint provided between the two brackets of the panel.

FIG. 4 is a perspective view of an undulating end piece for placement below a lower side of a lowermost mounting bracket of an overall system of photovoltaic panels, such that air can enter beneath the panels for natural convection cooling of the panels.

FIG. 5 is a sectional view taken along the line 5-5 of FIG. 3 illustrating details of a lateral expansion joint between adjacent brackets.

FIG. 6 is a top perspective view similar to that which is shown in FIG. 3, but from an opposite side.

FIG. 7 is a sectional view taken from the side and showing how adjacent similar mounting brackets overlap each other vertically with a lower side of a higher bracket overlapping an upper side of a lower bracket to define an overlapping portion between adjacent brackets.

FIG. 8 is a perspective view of adjacent brackets from adjacent panels and illustrating wiring for the J-boxes that facilitate electric coupling of adjacent panels together and with photovoltaic cell stack assemblies removed.

FIG. 9 is a top perspective view of a photovoltaic cell panel including both a pair of brackets and a photovoltaic cell stack assembly, and configured as a lower most panel such that a pair of undulating end pieces are provided beneath a lower side of the panel.

FIG. 10 is a perspective view of portions of a pair of panels resting upon a roof and showing a portion of the undulating end piece and the air circulation system of this invention.

FIG. 11 is a perspective view of a portion of a roof with a series of panels thereon and with photovoltaic cell stack assemblies on two of the panels removed and with arrows depicting pathways for airflow beneath the panels.

FIG. 12 is a perspective view of edge flashing for use at lateral sides of panels at lateral edges of an overall system of panels for water tight integration with shingles upon the roof.

FIG. 13 is a perspective view of a portion of a roof with the edge flashing of FIG. 12 in use adjacent lateral edges of a series of panels.

FIG. 14 is a schematic of a series of solar panel tiles each linked together and to a combiner box as well as to an inverter and sub-panel to define an overall photovoltaic power generation system according to this invention.

FIG. 15 is an exploded perspective view of a roof with a plurality of photovoltaic elements mounted thereon according to an alternative embodiment of this invention which does not utilize brackets. In this view, the panel elements are exploded away from both stringers/battens and the stringers are also exploded away from the roof, as well as bottom vents between the stringers.

FIG. 16 is a detail partially exploded perspective view of a portion of that which is shown in FIG. 15 and illustrating how bottom vents are interposed between stringers, and how additional spacer donuts are utilized as well as trim on the photovoltaic panels and lateral edge flashing to integrate the array of panels into the overall roofing of the system.

FIG. 17 is a perspective view of a portion of an underside of one of the photovoltaic panels and one of the stringers, and showing how a clip is utilized to hold a lower edge of the photovoltaic panel through bottom trim to the roof.

FIG. 18 is a perspective view similar to that which is shown in FIG. 17 but with the photovoltaic panel shown attached to the stringer through the clip.

FIG. 19 is a perspective view similar to that which is shown in FIGS. 17 and 18, but with the additional showing of the bottom vent in position adjacent the lower edge of the photovoltaic panel.

FIG. 20 is a perspective view of a photovoltaic panel from above and illustrating how trim elements around a perimeter of the photovoltaic panel are coupled together and integrated with the photovoltaic panel.

FIG. 21 is a perspective view of a corner of the photovoltaic panel trim elements showing how the trim elements are coupled together.

FIG. 22 is an end elevation view of side trim portions of the photovoltaic panel trim.

FIG. 23 is an end elevation view of bottom trim portions of the trim on the photovoltaic panel.

FIG. 24 is an end elevation view of top trim portions of the overall trim system for the photovoltaic panel.

FIG. 25 is a side elevation view of an uppermost portion of an array of photovoltaic panels according to this alternative embodiment and illustrating how a top vent is utilized to integrate an upper edge of uppermost photovoltaic panels into the roofing system to facilitate airflow and effectively shed water over the photovoltaic panels within the system of this invention.

FIG. 26 is a side elevation view of a pair of photovoltaic panels shown mounted upon a portion of roof and illustrating how the adjacent photovoltaic panels interlock together and how they are mounted through the stringers to the underlying roof.

FIG. 27 is a side elevation view of a lowermost portion of the array of photovoltaic panels illustrating how lower trim on the lowermost photovoltaic panel is mounted to the roof and relative to the bottom vent.

FIG. 28 is a perspective view of a portion a cell support structure on a lowermost portion of a panel beneath cells of the panel according to an embodiment where ports are provided and to which a door can be removably located for accessing electronics within the panel.

FIG. 29 is a perspective view similar to FIG. 28 but showing less detail of the port itself and more detail of the overall cell support structure according to the embodiment of FIG. 28.

FIG. 30 is a perspective view of a pair of panels with one panel having cells thereon and the other panel showing only the cell support structure with the cells removed, and according to the embodiment of FIG. 28, where ports are supplied and to which a door can be removably placed so that space beneath the panel can be accessed, such as for inspection, repair or replacement of electronics associated with the panel.

FIG. 31 is a perspective view similar to that which is shown in FIG. 28, but from a different perspective looking down on the port and door of the embodiment of FIG. 28, with cell electronics shown in broken lines mounted to a tray portion of the door.

FIG. 32 is a further perspective view of that which is shown in FIG. 28 with the door closed within the port and viewing from below the space beneath the cells and within the cell support structure inboard of the port, with a form of electronics such as an inverter shown in broken lines mounted to an underside of a tray portion of the door.

FIG. 33 is a detail of an alternative support clip for holding wiring associated with the photovoltaic cells of the array of panels.

### DETAILED DESCRIPTION OF THE PREFERRED EMBODIMENT

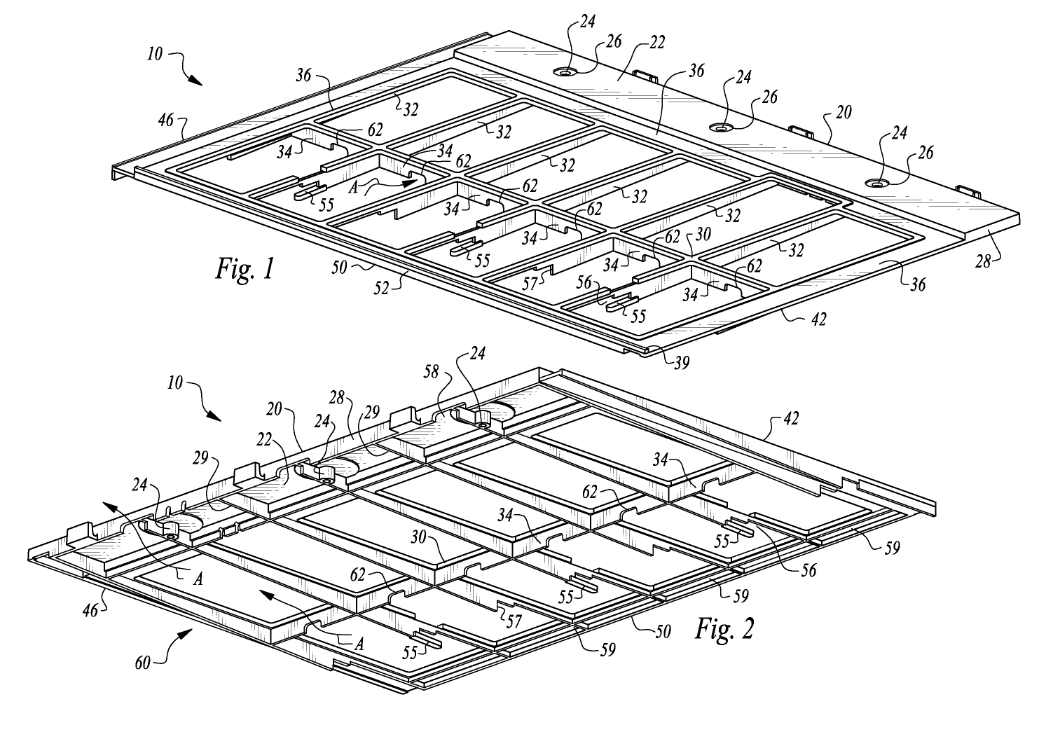

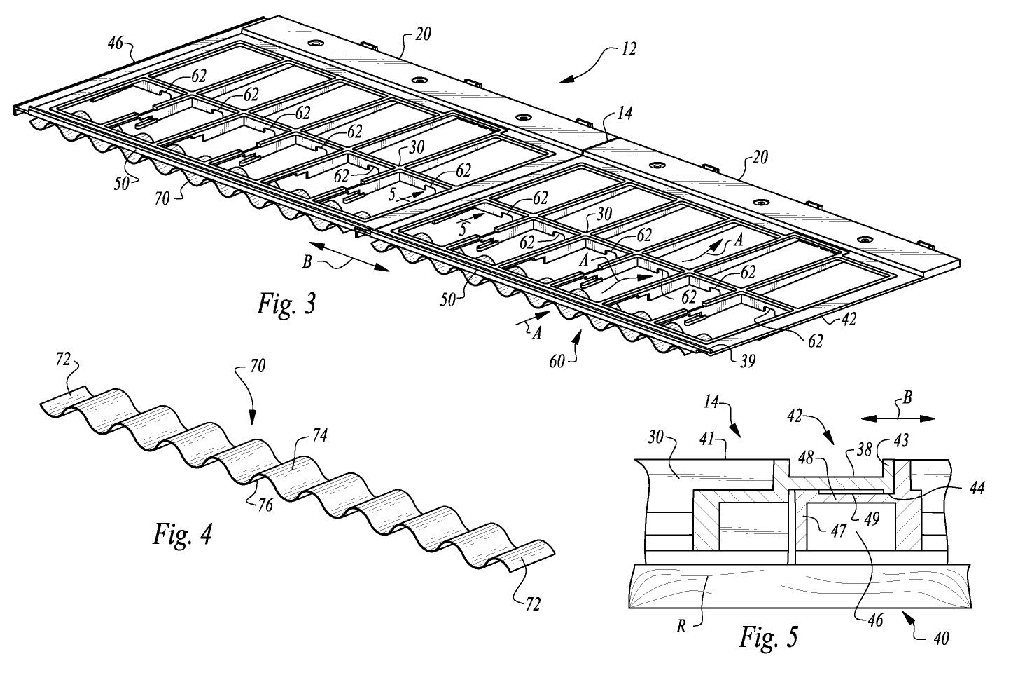

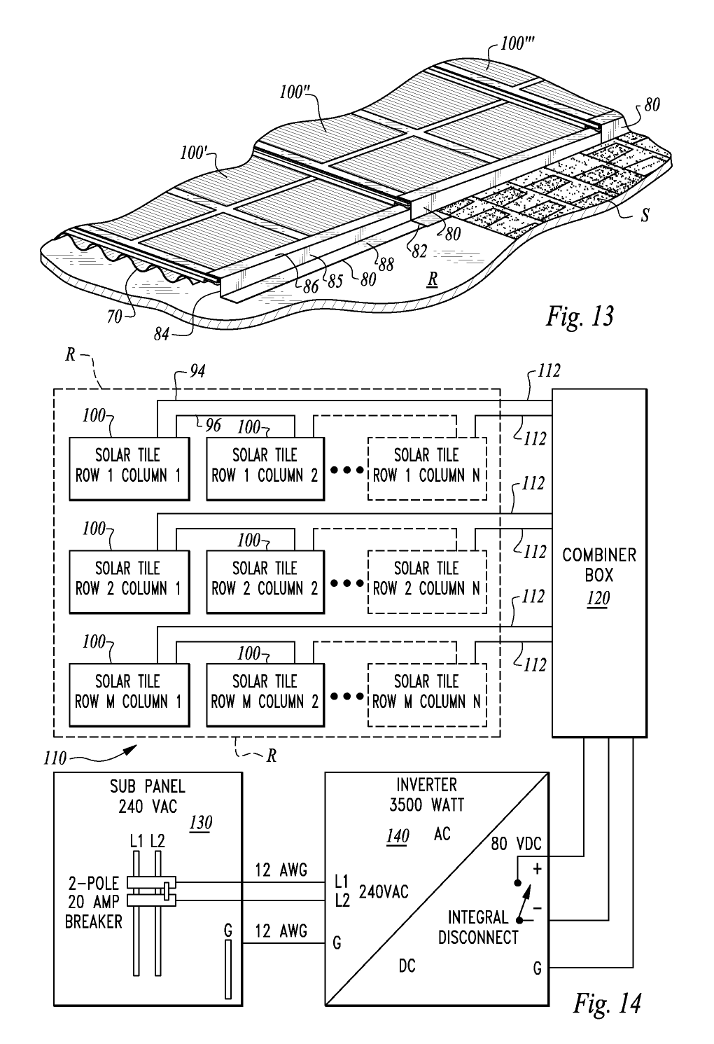

Referring to the drawings, wherein like reference numerals represent like parts throughout the various drawing figures, reference numeral 10 is directed to a bracket (FIGS. 1 and 2) for a roof mounted photovoltaic power generation system. The brackets 10 are provided in pairs 12 (FIG. 3) which together support a photovoltaic cell 102 stack assembly to form a panel 100 (FIG. 9). The panel 100 can act similar to a shingle S (FIG. 13) upon the roof R to shed water and protect structural portions of the roof. The brackets 10 interlock together laterally and vertically while accommodating airflow therebeneath for cooling. The brackets also accommodate thermal expansion and have edge details to facilitate airflow and to provide water preclusion. The brackets are also configured to facilitate interconnection of an electric subsystem 110 for combining adjacent panels 100 together as part of the overall photovoltaic power generation system.

In essence, and with particular reference to FIGS. 1-3, basic details of the bracket 10 are described. The bracket 10 is typically utilized in pairs 12 (FIG. 3) as a structural portion of a panel 100 (FIG. 9) also supporting photovoltaic cell 102 stack assemblies thereon. The brackets 10 each include a mounting rail 20 at an upper side and a bottom rail 50 at a lower side. A cell support structure 30 is interposed between the mounting rail 20 and bottom rail 50. A lateral joint 40 defines lateral sides of each bracket 10. The lateral joint 40 is configured so that it can interface with lateral edges of adjacent brackets 10 for lateral interconnection of multiple brackets 10, either of a common panel 100 (where the joint 40 is an expansion joint 14 (FIGS. 3 and 9) in the middle of the panel 100) or lateral interconnection of adjacent panels 100.

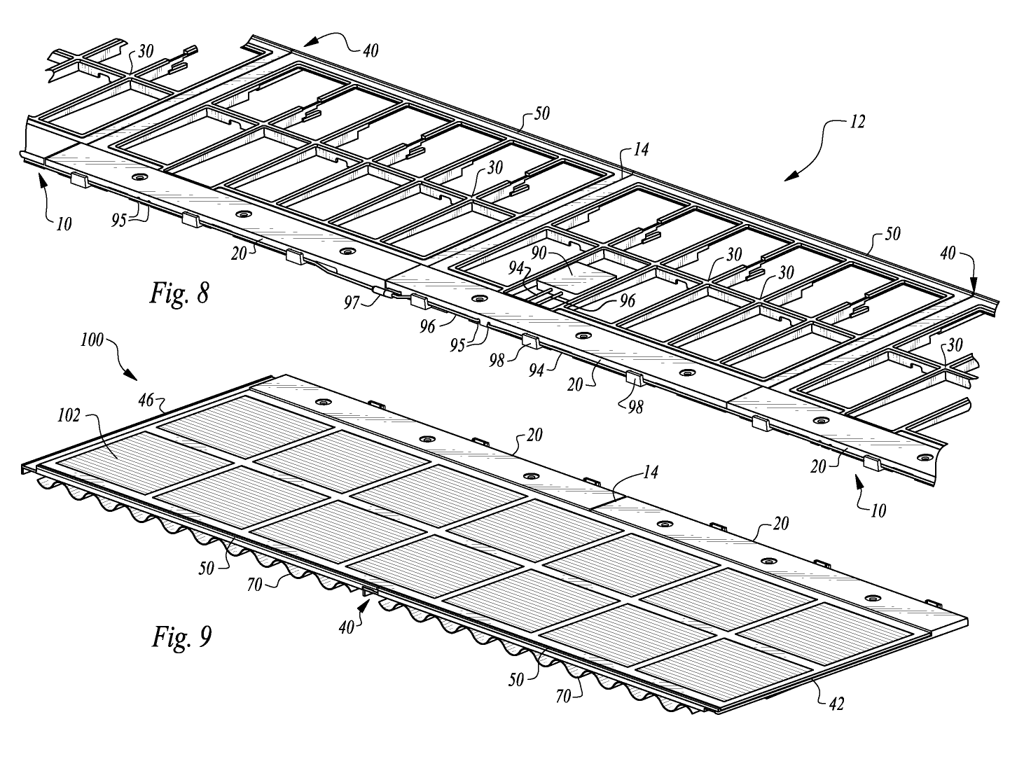

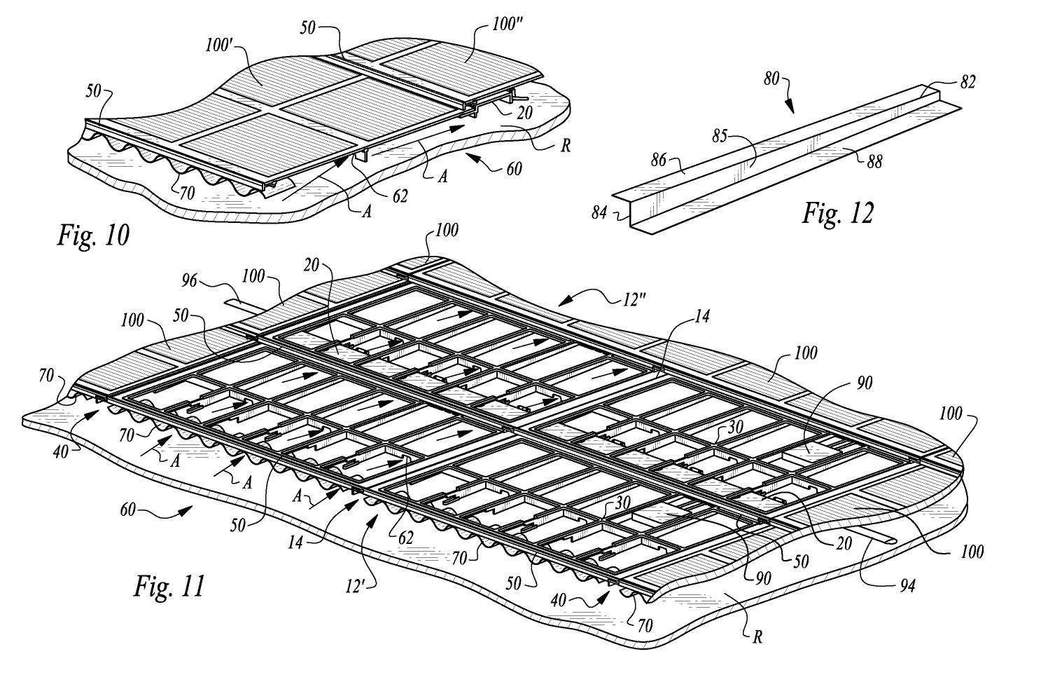

An air circulation system 60 routes air beneath the brackets 10 so that by natural convection air can be circulated beneath the brackets 10 and cool the brackets 10 and associated photovoltaic cell stack assemblies 102. An end piece 70 (FIGS. 3, 4, 9-11 and 13) is provided adjacent the bottom rail of a lowest bracket in a series of vertically spaced brackets 10. The end piece 70 holds up this lower side of the lowermost bracket so that air can pass beneath the bracket 10 and be routed beneath the series of brackets 10 for cooling. Edge flashing 80 (FIGS. 12 and 13) is provided so that water is prevented from migrating around the brackets 10 or panels 100 laterally. A J-box 90 (FIG. 8) is provided for each panel 100 to combine power from photovoltaic cells 102 of each panel 100 and allow the power from each panel 100 to be combined together into strings which can then be routed to a combiner box before being passed on to an inverter 140 and sub-panel 130 for effective utilization of the electric power from the system. An electric subsystem 110 (FIG. 14) is described which utilizes the panels 100 formed of brackets 10 according to this system.

More specifically, and with particular reference to FIGS. 1-3, specific details of the bracket 10 are described, according to a preferred embodiment. Each bracket 10 is preferably similar in form and in this preferred embodiment is comprised of a mounting rail 20 (FIGS. 1 and 2), a cell support structure (FIGS. 1 and 2), a lateral joint (FIG. 5) and a bottom rail 50 (FIGS. 1, 2 and 7). Each bracket 10 most preferably provides only half of the structural under support for a panel 100 (FIG. 9). Thus, a pair 12 of brackets 10 are provided together along with the photovoltaic cells 102 within a stack assembly to complete the panel 100 (FIG. 3). In this way, an expansion joint 14 (FIG. 3) is provided between the two brackets 10 within each pair 12. Note that the expansion joint 14 is the same as the lateral joint 40 with different terminology used depending on whether the brackets 10 are coming together at a midpoint within a panel 100 or at a lateral edge of a panel 100 where adjacent panels 100 are joined together laterally.

An upper side of each bracket 10 is defined by the mounting rail 20. The mounting rail 20 provides a preferred form of mounting portion for the bracket 10. This mounting rail 20 preferably includes a planar surface 22 with holes 24 passing therethrough for fasteners to pass and then penetrate the roof R. Preferably, a recess 26 surrounds each hole 24 to provide relief into which a head of the fastener can reside, such as the head of a roofing nail, or the head of a fastening screw.

A perimeter skirt 28 preferably surrounds at least an upper edge of the planar surface 22 of the mounting rail 20. The perimeter skirt 28 preferably extends perpendicularly down from the planar surface 22. Gussets 29 are preferably formed beneath the planar surface 22 to provide structural support and rigidity to the mounting rail 20 (FIG. 2). The perimeter skirt 28 also helps to rigidify the bracket 10.

The mounting rail 20 is typically covered by a bottom rail 50 of a higher adjacent similar bracket 10 of a separate higher adjacent panel 100 (FIGS. 7 and 11). However, a highest panel 100 will be formed of brackets 10 which have mounting rails 20 which are not covered by adjacent brackets 10 or panels 100. Instead, the highest panels 100 will have their mounting rails 20 typically covered by shingles placed on the roof R and allowed to have lower shingle edges overlap the mounting rail 20 portion of the bracket 10. If desired, a tapering piece of filler material can be provided directly above this highest bracket so that rather than having a somewhat abrupt transition in thickness at the perimeter skirt 28 of the mounting rail 20, a more gradual transition to greater thickness can be provided.

Most preferably, this perimeter skirt 28 is kept ventilated so that air circulating beneath the brackets 10 can escape out of the perimeter skirt 28, such as through gaps 58 (FIG. 2). In a preferred form of the invention, this highest row of brackets 10 are near a ridge of the roof and a ridge vent is provided which overlaps the mounting rail 20 portion of the bracket 10 and allows air circulating beneath the brackets 10 to escape. Such ridge vents are known in the composition shingle roofing construction trades.

The cell support structure 30 is provided below the mounting rail 20 and extending down to the bottom rail 50. This cell support structure 30 is generally formed of a series of vertical ribs 32 and at least one lateral rib 34 extending substantially perpendicular to the vertical ribs 32. A perimeter deck 36 surrounds a perimeter of this cell support structure space with the perimeter deck 36 generally planar with upper sides of the vertical ribs 32 and lateral rib 34. A trough 38 (FIG. 5) preferably is formed in the perimeter deck 36 and defines a slightly recessed depression in the perimeter deck 36. This trough 38 can accommodate adhesive to hold the photovoltaic cell 102 stack assembly within the cell support structure 30 space and against the perimeter deck 36 (FIG. 7). A lip 39 defines a lowermost edge of the cell support structure 30 and acts as a barrier to keep the photovoltaic cell 102 stack assembly from migrating downward out of the cell support structure 30 space.

The cell support structure 30 of the bracket 10 adds some rigidity to the overall panel 100 when two brackets 10 are provided laterally together along with a photovoltaic cell 102 stack assembly. However, the photovoltaic cell 102 stack assembly also adds rigidity and strength to the resulting panel 100. Windows between adjacent vertical ribs 32 and lateral rib 34 are open until covered by the photovoltaic cell 102 stack assembly. With such a rib cell support structure 30, the overall bracket 10 has a minimum of material and thus maintains light weight while still providing strength where required to keep the panel 100 sufficiently strong to resist weight loads, such as from snow loading or from maintenance personnel walking on the panels 100.

The lateral joint 40 (FIG. 5) is formed of an over tab 42 on one lateral side of the bracket 10 and an under tab 46 on the other lateral side of the bracket 10. The over tab 42 and under tab 46 fit together with the over tab 42 over the under tab 46. A cell support plane 41 is defined above the lateral joint 40 formed of the photovoltaic cell 102 stack assembly which rests upon this cell support plane 41.

The over tab 41 extends to a tip 43. The tip 43 extends primarily upward from the trough 38, but also extends slightly downward to a heel 44. The heel 44 rests within an expansion slot 49 formed on a shelf 48 of the under tab 46. A perimeter wall 47 is located beneath the shelf 48 and helps support the shelf 48. The heel 44 can ride within this expansion slot 49 some distance to allow for lateral motion therebetween (along arrow B of FIGS. 3 and 5), such as to decrease spacing when temperatures increase and increase spacing when temperatures decrease.

Such lateral expansion and contraction across the lateral joints 40 and expansion joint 14 (FIG. 3) allows the brackets 10 to accommodate temperature changes without damaging the panels 100 or causing the system to fail. In one embodiment the lateral joint 40 is formed with the heel 44 in a middle of the expansion slot 49 with the brackets 10 and other portions of the panel 100 substantially at room temperature. In this way, the bracket 10 and panel 100 can undergo thermal expansion or contraction away from room temperature either in a cooling direction or a heating direction and the heel 44 will have room to move in either direction within the expansion slot 49 before damage will occur to the brackets 10 or the panel 100.

Preferably, the lateral joint 40 (and expansion joint 14) are not fitted with any adhesive, but rather are allowed to float relative to each other. Both the over tab 42 and under tab 46 are able to shed water in a downward direction while overlapping each other, such that water is prevented from migrating beneath the bracket 10 around or through this lateral joint 40. When configured as the expansion joint 14, the photovoltaic cell 102 stack assembly further covers the expansion joint 14 to resist water migration therethrough except at the mounting rail 40 (FIGS. 3 and 9).

The bottom rail 50 defines a lowermost portion of each bracket 10 (see particularly FIG. 2). The bottom rail 50 includes an edge wall 52 defining an extreme lower side of each bracket 10. Feet 53 (FIG. 7) define an underside of the bottom rail 50 which are configured to rest upon the mounting rail 20 of an adjacent lower bracket 10 and most particularly just below the mounting rail 20 and over the cell support structure 30 as well as over the photovoltaic cells 102 of the stack assembly of the next lower panel 100 (FIG. 7). In such an arrangement, thermal expansion and contraction can be accommodated (along arrow C of FIG. 7) by sliding of the feet 53 up or down along the pitch of the roof R (horizontally in FIG. 7).

The bottom rails 50 are configured not to rest on the roof R directly, but rather to rest upon an adjacent lower bracket 10. A wind clip 55 defines a portion of the underside of each bracket 10 adjacent the bottom rail 50. These wind clips 55 are preferably in the form of elongate rigid structures extending downwardly as a portion of an underside of each vertical rib 32. These wind clips 55 are configured so that they can rest on the roof R and fit within the gaps 58 of the perimeter skirt 28 in the mounting rail 20 of the next lower bracket 10. In this way, the bottom rail 50 of each bracket 10 is held down by the mounting rail 20 of the next lower bracket 10.

The wind clip 55 includes a clearance space 56 above each wind clip 55. A step 57 defines an abutment which can be provided on every other rib 32, rather than a wind clip 55, and help to keep the brackets 10 aligned adjacent each other. Preferably, the brackets 10 are not placed with the steps 57 abutting the mounting rails 20 when installed, but rather with a small gap therebetween to accommodate some thermal expansion that would tend to drive adjacent brackets 10 against each other. The bottom rail 50 also preferably includes stiffeners 59 in the form of horizontal and vertical ribs adjacent the bottom rail 50 to help strengthen the bottom rail 50 and also supporting the feet 53 of the bottom rail 50. The gaps 58 (FIG. 2) in the perimeter skirt 28 of the mounting rail 20 are sized to receive the wind clips 55 therein, while also providing openings for air circulation therethrough.

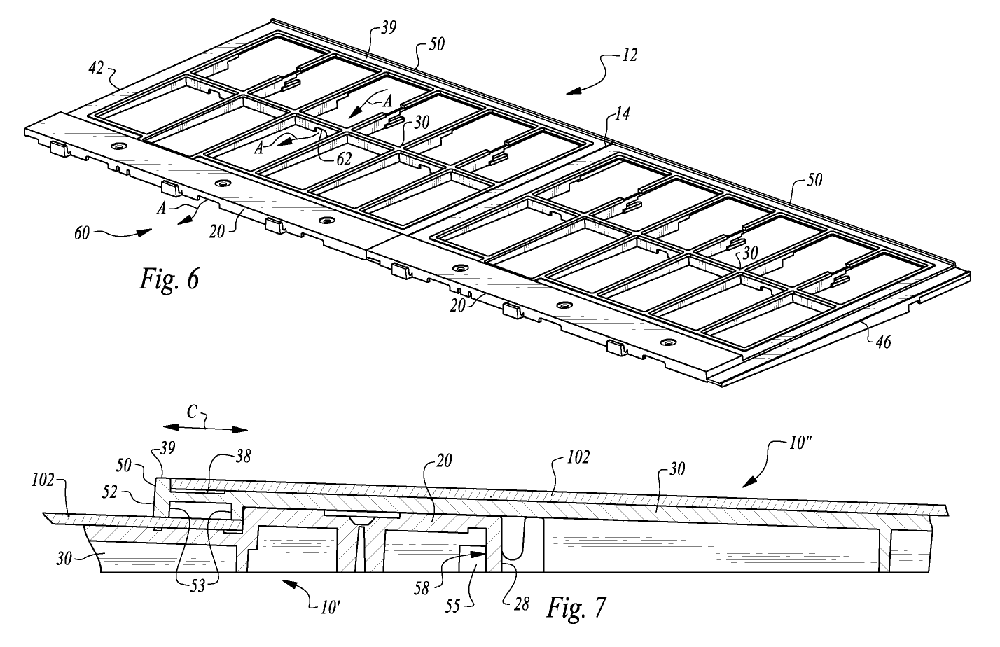

With particular reference to FIGS. 3, 6, 10 and 11, details of the air circulation system 60 of this invention are described, according to a preferred embodiment. The brackets 10 are configured to interconnect together in a way that preserves an air circulation system 60 driven by natural convection to help cool the brackets 10 and the overall photovoltaic power generation system. This air circulation system 60 begins with end pieces such as the undulating end piece 70 (FIG. 4) which are fitted beneath the bottom rail 50 of a lowermost bracket 10 of an overall power generation system (FIG. 11).

The bottom rail 50 is not configured to have the feet 53 rest upon the roof R. Rather, the feet 53 are configured to rest upon an adjacent lower mounting rail 20 or the cell support structure 30 just below the mounting rail 20. Thus, the end piece 70 is provided to hold up the bottom rail 50 of the bracket 10 defining a lowermost portion of the overall system.

This end piece 70 is preferably in the form of an undulating end piece with lateral ends 72 spaced from each other and with troughs 74 and crests 76 alternating between the ends 72. Airflow is thus easily accommodated through the end piece 70 and beneath the brackets 10. While the end piece 70 is shown relatively shallow in extent toward the mounting rail 20, most preferably the end piece is deep enough toward the mounting rail 20 to abut the steps 57 (FIG. 2). In this way the lowest brackets 10 in the series of panels 100 is fully supported beneath the bottom rail 40 by the end piece 70. The deeper end piece can be captured by the wind clip 55 to further secure the end piece to the bracket 10.

Airflow (along arrow A) passes through the troughs 74 and crests 76 in the undulating end piece 70. This air is then located beneath the bracket 10. Heat within the bracket 10 or within other portions of the panel 100 or roof R is allowed to transfer to the air in this space beneath the bracket 10. With the air having been heated, natural convection causes the air to rise. While the photovoltaic cell 102 stack assembly keeps the air from rising purely vertically, passages 62 are preferably formed in the lateral rib 34 which allow the air to pass beneath the cell support structure 70 from the bottom rail 50 up to the mounting rail 20.

The gaps 58 in the perimeter skirt 28 allow the air to continue from beneath the mounting rail 20 and to under the next bracket 10 (arrow A of FIGS. 3 and 11). This airflow can continue beneath each of the brackets 10 until the highest bracket 10 is reached. The air can then escape out the gaps 58 in the highest brackets 10. With such airflow, a maximum temperature of the panels 100 is minimized. Different patterns of gaps 58 and passages 62 can be provided to route the air where desired for maximum cooling heat transfer, to optimize performance of the power generation system.

With particular reference to FIGS. 12 and 13, details of the edge flashing 80 are described, according to a preferred embodiment. The edge flashing 80 is provided to keep water from migrating beneath the brackets 10 and panels 100 along lateral edges of the overall system. While the lateral joints 40 preclude water from getting beneath the panels 100 where panels 100 are spaced laterally from each other, eventually the panels 100 at a perimeter edge of the overall system are reached. The edge flashing 80 is then utilized to transition from the panels 100 to shingles S upon the roof R.

With particular reference to FIG. 13, a series of three panels 100′, 100″, 100′″ are shown stacked adjacent each other with an undulating end piece 70 at a lower side of the lowermost panel 100′. The edge flashing 80 is configured with upper ends 82 opposite lower ends 84 and with a top plate 86 spaced from a bottom plate 88 by a web 85, with the plates 86, 88 generally parallel with each other. The top plate 86 is configured to rest upon an upper surface of the panel 100. The bottom plate 88 is configured to rest adjacent the roof R with shingles S resting on top of the bottom plate 88. The web 85 joints the two plates 86, 88 together and precludes water from migrating laterally beneath the panels 100. The edge flashing 88 overlaps somewhat at the ends 82, 84 to further preclude water migration at seams between adjacent pieces of edge flashing 80.

Because each of the brackets 10 and associated photovoltaic cell 102 stack assemblies taper somewhat in thickness with a thinnest edge adjacent the mounting rail 20 and a thickest edge adjacent the bottom rail 50, the web 85 preferably tapers from being shorter at the upper ends 82 to being longer at the lower ends 84. In this way, such tapering of the brackets 10 and overall panels 100 can be accommodated. Typically, the edge flashing 80 is formed by cutting rigid planar material, such as galvanized steel, and bending it to have the shape depicted in FIG. 12.

With particular reference to FIG. 8, particular details of a J-box 90 and associated electrical interconnection for the photovoltaic cells 102 within each panel 100 are described, according to a preferred embodiment. The J-box 90 is preferably an electronic device embedded within a waterproof resin to make it entirely waterproof.

Each photovoltaic cell 102 stack assembly is preferably formed of a series of separate cells 102 (most typically fourteen in two rows of seven a piece). In a simplest form of the invention, as few as one photovoltaic cell could be provided on each panel 100 of two brackets 10. Photovoltaic cells 102 are shown in this embodiment as a preferred form of photovoltaic element. Other photovoltaic elements could be substituted, such as thin film photovoltaic materials or structures, either now known or later developed. These separate cells 102 are joined together in series electrically. They are then laminated together between layers of waterproof materials.

Particularly, this layering preferably involves a low iron glass as a top layer, followed by a low melt temperature plastic layer such as EVA, followed by the photovoltaic cells themselves, followed by another low melt temperature plastic layer such as EVA, followed by a layer of Tedlar. This layering stack is laminated to further preclude water penetration. This stack is followed by an adhesive for mounting to the perimeter deck 36 of the cell support structure 30 of the bracket 10. One adhesive that can be utilized is known as adhesive 804 Dow Flexible Adhesive provided by the Dow Chemical Company of Midland, Mich.

Because the photovoltaic cells 102 are encased within this sandwich, electrical connections between adjacent photovoltaic cells are kept from shorting out, such as due to the presence of water when rain is falling on the roof. At the J-box 90, separate conductors from the series of photovoltaic cells 102 are routed into the J-box 90 so that all of the power from the series of photovoltaic cells 102 within the panel 100 are received at the J-box 90. This power is then routed through leads 94, 96. The leads 94, 96 allow adjacent panels 100 to be coupled together, typically in series.

Support clips 98 preferably extend from the perimeter skirt 28 of the mounting rail 20. These support clips 98 can hold the leads 94, 96 therein to prevent them from experiencing damage. The leads 94, 96 are preferably insulated to allow direct exposure to the elements. Slots 95 are provided at strategic locations in the perimeter skirt 28 of the mounting rail 20 to allow the leads 94, 96 to extend through the perimeter skirt 28 before bending 90° and extending along the perimeter skirt 28 and over the support clips 98. Couplers 97 allow the leads 94, 96 to be interconnected together to connect a series of such panels 100 together in series.

Each series connection of such panels 100 can be combined together through an end lead 112 extending into a combiner box 120 to further combine power from individual panels 100 and to configure the overall power from the series of panels 100 into power having the desired voltage and current. Inverters 140 can be utilized downstream from a combiner box 120 if it desired to generate AC power. Transformers can be utilized if a different current and voltage is desired.

The inverter 140 is typically coupled to a sub-panel 130 where the power can be effectively utilized as AC power service within a residential structure or sold to a power company, or put to other beneficial use. The converter box 120, inverter 140 and sub-panel 130 together form an electrical subsystem 110 which receives end leads 112 from separate strings of panels 100 through function of the leads 94, 96 and J-box 90.

Each panel 100 (also referred to as a “tile” or “solar tile”) is typically provided in an array including N columns and M rows. Typically, each row is coupled in series and routed to a common combiner box 120 through end leads 112. In one form of the invention, panels 100 are coupled together in series until the desired voltage for the system is achieved. Then multiple such strings of series connections of panels are joined together in the combiner box 120 to increase the current provided by the overall system.

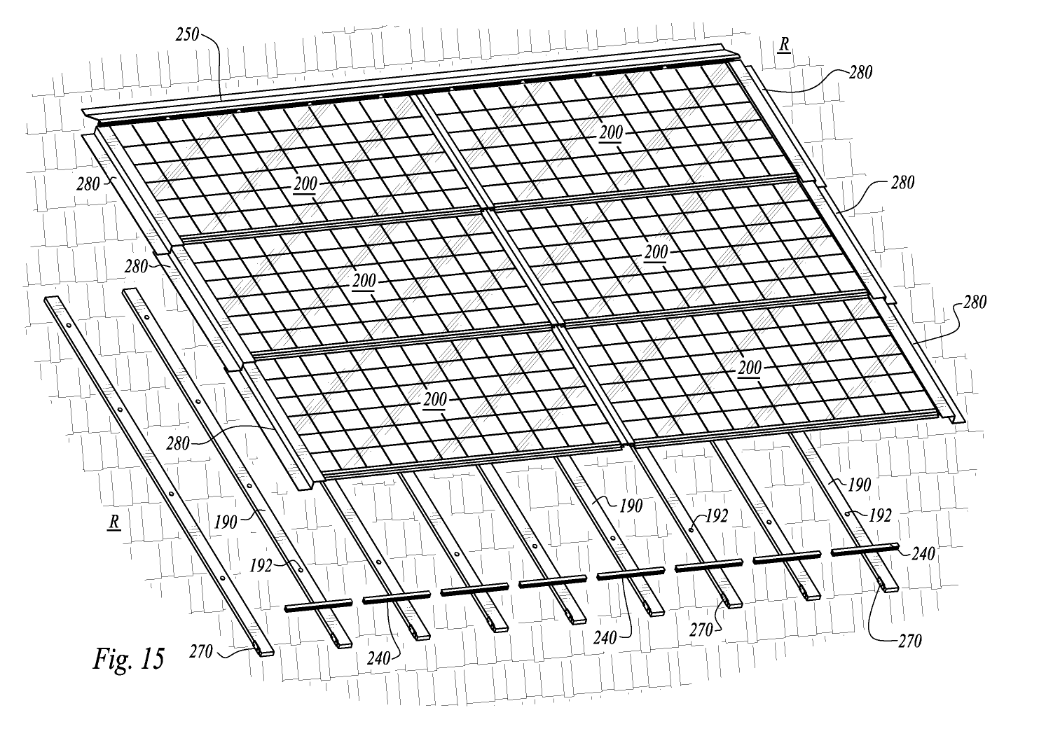

With particular reference to FIGS. 15-27, details of an alternative roof mounting system for photovoltaic power generation equipment is described. This alternative system utilizes panels 200 which are configured to be mounted to a roof R without brackets, such as the brackets 10 described above. Rather, the panels 200 mount directing to the roof R, typically through a standoff spacer such as stringers 190, and with appropriate trim 210, 220, 230 on each panel 200, and appropriate venting 240, 250 and flashing 280 to integrate the panels 200 into the roof R.

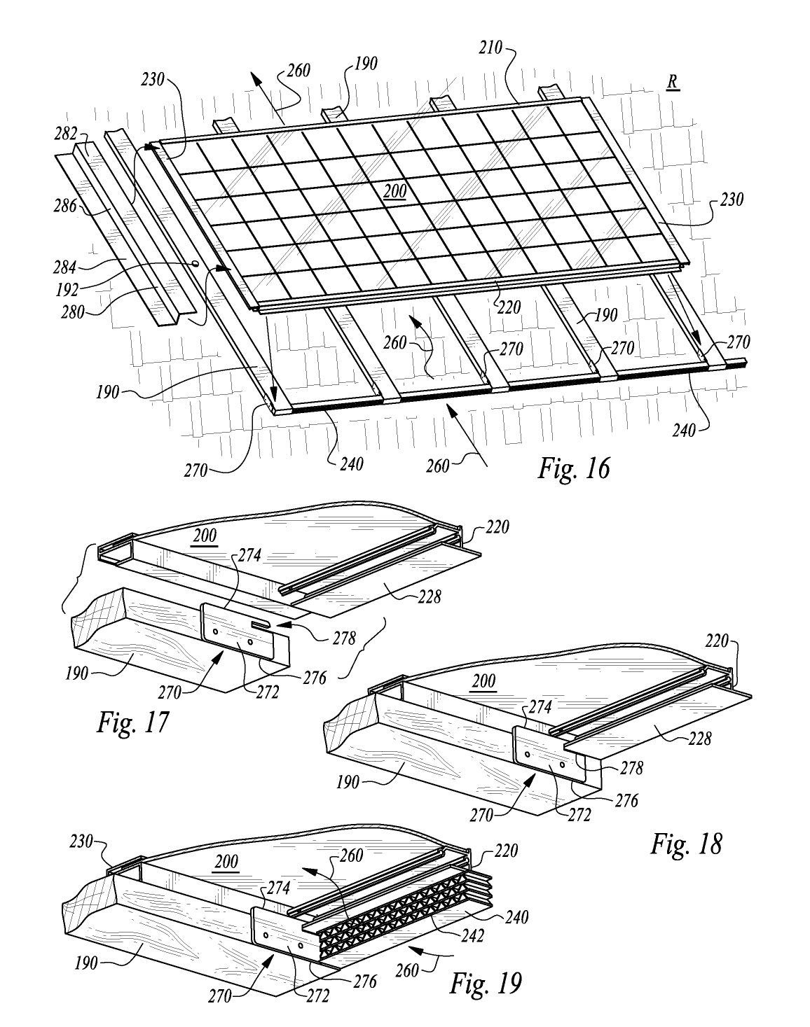

The roof R typically includes a vapor barrier as an uppermost barrier and planar roof sheeting material or other roof structural material beneath the vapor barrier. Other portions of the structure support the roof R above a foundation of the overall structure. The stringers 190 are preferably continuous, but could be broken into separate segments. Donut spacers or some other form of additional spacer 192 is also provided upon portions of the stringers 190 at positions midway between upper and lower edges of each panel 100 so that midpoints of each panel 200 are supported, such as to carry snow loads. One form of such additional spacers is shown in FIGS. 15 and 16. While shown with a width smaller than the stringers 190, the additional spacers could be wider and longer to accommodate the preferences of the designer. As an options these additional spacers 192 could be built into the stringers 190.

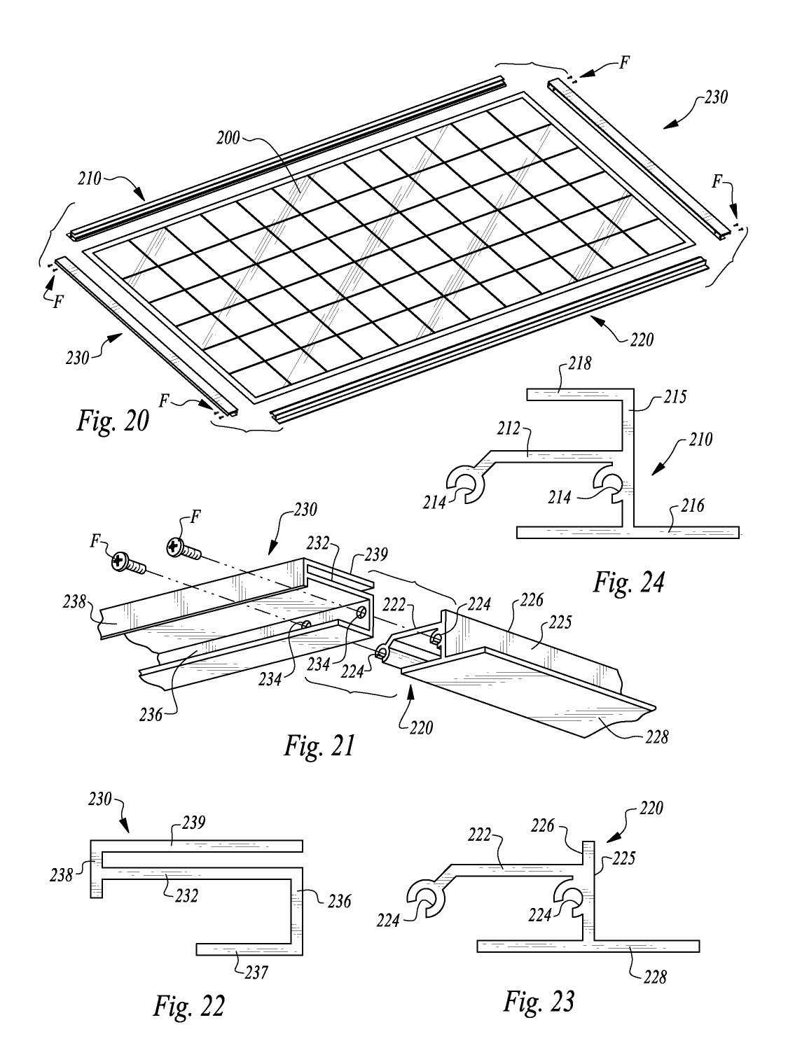

In essence, and with particular reference to FIG. 16, basic details of this alternative system are described, according to a most preferred arrangement for this alternative embodiment. The panels 200 are similar to the panels 100 described previously, except that they are fitted with trim around a perimeter thereof to facilitate interlocking together and coupling to the roof R. In particular, this trim on the panel 200 includes top trim 210 along an upper edge of the panel 200, bottom trim 220 adjacent a bottom edge of the panel 200 and side trim 230 on each lateral side of the panel 200. These trim pieces 210, 220, 230 are coupled together, such as through fasteners F (FIG. 20) to surround a perimeter of the panel 200.

Stringers 190 are provided upon the roof R with the panels 200 mounted directly upon the stringers 190. The panels 200 overlap slightly with bottom trim of each panel resting upon top trim of a next sequentially lower panel 200. A bottom vent 240 fits in a space between the stringers, and provides access into an air circulation pathway 260 beneath the panels 200. A top vent 250 resides over an upper edge of an uppermost panel 200 within the overall system to keep water from migrating under the panels 200, but allow air to pass into and out of the air circulation pathways 260 beneath the panel 200. Edge flashing 280 is provided to integrate lateral edges of most lateral panels 200 within the system into the roof R and beneath other roofing material, such as shingles adjacent the lateral edges of the panels 200.

More specifically, and with particular reference to FIGS. 21-24, specific details of the trim 210, 220, 230 on the panel 200 are described. The top trim 210 (FIGS. 20 and 24) is located adjacent an upper edge of the photovoltaic panel 200. While the top trim 210 can be adhesively bonded or otherwise attached directly to the panel 200, most preferably the top trim 210 is captured to the panel 200 by being secured to the side trim 230 at ends of the top trim 210 and with the side trim 230 secured to the bottom trim 220, so that the entire trim 210, 220, 230 holds the panel 200 therein.

Most preferably, the top trim 210 has a constant cross-sectional form (FIG. 24), such that the top trim 210 can be conveniently extruded through an extrusion die having the desired contour. Alternatively, the top trim 210 could be formed by injection molding or other manufacturing processes.

The preferred cross-sectional form for the top trim 210 generally includes a spine 215 generally extending in a first direction adapted to be oriented substantially perpendicular to a plane in which the panel 200 is oriented. A support shelf 212 extends laterally from the spine 215. The support shelf 212 defines a surface upon which the panel 200 rests. This support shelf 212 also defines a surface to which an adhesive or fastener can be optionally utilized to secure the panel 200 to the top trim 210.

Fastener slots 214 are preferably located just below the support shelf 212. These fastener slots 214 have a generally circular hollow interior form surrounded on at least a majority thereof by a cylindrical sleeve. Fasteners F, such as screws, can be sized to thread into the recesses in the fastener slots 214 and inside of this sleeve, with the threads of the fasteners F engaging the sleeves, so that the fasteners F hold tight within the fastener slots 214. Preferably, a pair of such fastener slots 214 are provided, with one at an extreme end of the support shelf 214, but slightly below the support shelf 212, so as to not interfere with the positioning of the panel 200 upon the support shelf 212, and with one fastener slot 214 located at an intersection between the support shelf 212 and the spine 215. As an alternative, a single fastener slot 214 or more than two fastener slots 214 could be provided.

A foot 216 defines a lowermost portion of the top trim 210. This foot 216 preferably extends in opposite directions perpendicularly from a lower end of the spine 215. The foot 216 is adapted to rest directly upon the stringers 190 or other support structures beneath the panels 200 and above the roof R. The foot 216 is sufficiently large to support weight of the panel 200. Furthermore, the foot 216 preferably is sufficiently large that a fastener can be provided passing through the foot 216 and extending into the stringer 190 or other underlying support structure. Such a fastener could be a screw, a nail, a rivet, a bolt or some other form of fastener F for securing an upper edge of the panel 200 to the roof R. To some extent, such a fastener F is optional in that the separate panels 200 are coupled to adjacent panels 200 and it is conceivable that only some of the panels 200 would be fastened directly to the roof and other panels 200 would be held adjacent the roof by their connection to adjacent panels.

However, most preferably each panel 200 has top trim 210 thereof fastened directly to the roof R, through the stringers 190 or other underlying support structures to equally distribute fastening forces over the entire power generation assembly and minimize the potential for separation of the panels 200 from the roof R, such as due to wind loads or earthquakes. In one form of the invention, the top trim 210 could be the only required trim on the panel 200 and fastening of each panel 200 could be entirely by use of the fastener F passing into the stringer 190 or other spacer.

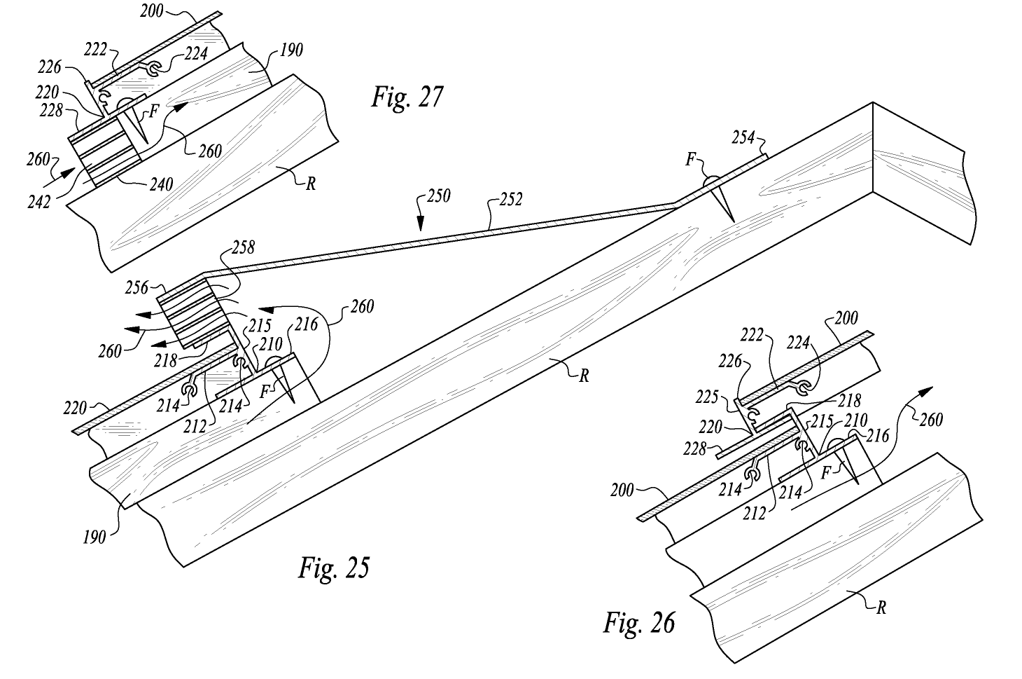

The top trim 210 also preferably includes an upper plate 218 extending laterally from the spine 215 at an upper end of the spine 215 opposite the foot 216. This upper plate 218 preferably extends in only a single direction away from the spine 215. The upper plate 218 allows for interlocking with bottom trim 220 on an adjacent higher panel 200, or can support a spacer 258 interposed between the top trim 210 and a lower end 256 of top vent flashing 252 associated with the top vent 250 (FIG. 25). While FIG. 26 shows bottom trim 220 of one panel 200 interlocking directly with top trim 210 of an adjacent lower panel 200 through the upper plate 218 of the top trim 210, it is conceivable that a spacer such as the spacer 258 could be provided between such adjacent panels 200 between the top trim 210, upper plate 218 and bottom trim 220, such that enhanced air circulation can be provided between each adjacent panel 200. Such a spacer 258 could be configured with a thickness similar to the spacer 258 provided beneath the lower end 256 of the flashing 252 of the top vent 250, or could be lower profile for such positioning between adjacent panels 200. As another alternative, such a spacer 258 could be selectively sized to cause the angle of each panel 200 to match an optimum angle for the latitude where the roof R is located.

With particular reference to FIGS. 20, 21 and 23, particular details of the bottom trim 220 are described according to this alternative embodiment. The bottom trim 220 is configured to be located adjacent a lower edge of each panel 200. The bottom trim 220 could be adhesively coupled, bonded or fastened to the lower edge of the panel 200. However, most preferably the bottom trim 220 is primarily coupled to the panel 200 by being fastened to the side trim 230 and top trim 210 in a manner completely surrounding the panel 200.

The particular preferred configuration for the bottom trim 220 includes a spine 225 extending up from a foot 228. A support shelf 222 extends laterally from a mid portion of the spine 225. The support shelf 222, spine 225 and foot 228 of the bottom trim 220 are preferably similar to corresponding portions of the top trim 210. Similarly, the bottom trim 220 preferably includes fastener slots 224 positioned similarly to the fastener slots 214 of the top trim 210 for accepting fasteners F to hold the bottom trim 220 to the side trim 230.

Uniquely, the bottom trim 220 preferably includes a stop 226 defined by an upper portion of the spine 225. This stop 226 helps to keep the panel 200 in position upon the support shelf 222 and from sliding past the stop 226, so that the stop 226 can support a lower edge of the panel 200 upon the bottom trim 220. While the foot 228 of the bottom trim 220 could be utilized with a fastener for directly attaching the bottom trim 220 to the underlying roof R, such as through the stringers 190, or other underlying support structures, most preferably the foot 228 of the bottom trim 220 is held in place by being located beneath the upper plate 218 of an adjacent lower panel 200 (FIG. 26) or through coupling to the clip 270 described below.

With such an arrangement, and by only affixing each panel 200 through the top trim 210 directly to the roof R, thermal expansion of each panel 200 is most readily accommodated. However, the foot 228 of the bottom trim 220 is preferably interlocked sufficiently with the upper plate 218 of the top trim 210, so that adjacent panels 200, when so interlocked, cannot be completely removed from each other, but merely accommodate some limited degree of movement therebetween. While the interlocking shown and described is preferred, other forms of interlocking or fastening could also be utilized, such as complementally sloped lap joints, dovetail joints, snap joints, etc.

The side trim 230 is shown in FIGS. 20-22. The side trim 230 is preferred to facilitate joining of the top trim 210 and bottom trim 220, and also helps support the overall panel. As an alternative, the side trim 230 could be omitted and the top trim 210 and bottom trim 220 could be attached directly to the panel 200 only. The side trim 230 has a contour including a support shelf 232 generally akin to the support shelves 212, 222 of the top trim 210 and bottom trim 220. An inner wall 236 extends down from one edge of the support shelf 232 and an outer wall 238 extends up from an opposite edge of the support shelf 232. A cover 239 extends back over the support shelf 232 from an upper end of the outer wall 238.

Fastener holes 234 are preferably formed in the inner wall 236. These fastener holes 234 are preferably spaced apart a distance similar to the fastener slots 214 in the top trim 210 and the fastener slots 224 in the bottom trim 220. These fastener holes 234 are preferably circular and have a size similar to a shaft of a fastener to be utilized to join the side trim 230 to the top trim 210 or bottom trim 220. Spacing between those fastener holes 234 is preferably similar to spacing between the fastener slots 214, 224 of the top trim 210 and bottom trim 220. Thus, when appropriate fasteners F are utilized passing through the fastener holes 234 and the side trim 230 and into the fastener slots 212, 224 of the top trim 220 and bottom trim 230, such fasteners F completely secure the side trim 230 to the top trim 210 and bottom trim 220 to provide a complete perimeter of trim for the panel 200.

The cover 239 overlies side edges of the panel 200. Such covers 239 provide additional support to hold the panel 200 adjacent the side trim 230 and keep the panels 200 from being displaced upwardly past the stop 226 on the bottom trim 220 and/or off of the support shelf 212 of the top trim 210. An appropriate bonding agent or fastener could alternatively or additionally be utilized in addition to the cover 239 to ensure that the panel 200 is held securely to the side trim 230.

The outer walls 238 of adjacent side trim 230 of adjacent panels 200 are preferably configured to abut directly adjacent each other. With such a configuration, zero clearance is provided between adjacent but laterally spaced panels 200. Typically, the panels 200 of this invention are provided upon a roof R which also has a separate moisture barrier underlying the stringers 190. Furthermore, the side trim 230 preferably is aligned with a stringer 190. Thus, the potential for water to migrate between adjacent but laterally spaced panels 200 through the underlying moisture barrier is minimized.

As an alternative, the side trim 230 could be provided with an overlapping joint similar to that disclosed in the first embodiment hereinabove (FIGS. 1-14) or could be provided with some other form of weatherproofing seal interposed between adjacent but laterally spaced panels 200. Preferably, any such joint can accommodate some degree of lateral thermal expansion or contraction therebetween.

With particular reference to FIG. 25, details of the top vent 250 are described according to this alternative embodiment. The top vent 250 is designed to allow the air circulation pathway 260 to extend out of an upper end of the panel 200 (along arrow 260 of FIG. 25). However, such air circulation must be maintained while also substantially precluding water migration beneath the panels 200. In one simple embodiment, when an uppermost panel 200 is located adjacent a peak of a roof R, a ridge vent can be utilized resting upon spacers such as the spacers 258 and extending over the peak of the roof R.

As an alternative, and particularly when an uppermost panel 200 is located spaced below the top ridge of the roof R, the top vent 250 shown in FIG. 25 is utilized. The top vent 250 includes flashing 252 extending from an upper end 254 to a lower end 256. The upper end 254 is configured to be fastened, such as with the fastener F, to the roof R. Shingles or other roofing material are provided overlapping the upper end 254 and fastener F so that water passes the upper end 254 before falling down onto the flashing 252 between the upper end 254 and the lower end 256.

The flashing 252 can include a bend between the upper end 254 and the lower end 256 sufficient so that the lower end 256 is adjacent and above the upper plate 218 of top trim 210 of an uppermost panel 200 by a distance similar to a thickness of a spacer 258 resting upon the upper plate 218. This spacer 258 can be built into the top vent 250 by being bonded to the flashing 252. As an alternative, the flashing 252 can be configured to be bent, such as to accommodate the particular pitch of the roof R involved. The flashing 252 is configured so that it extends downwardly as it extends from the upper end 254 to the lower end 256 along its entire length, so that no pooling of water occurs upon the flashing 252. Water would then fall off of the lower end 256 of the flashing 252 and down onto the uppermost panel 200.

Air circulation can occur through the spacer 258, such as through channels therein along arrow 260 of FIG. 25. A similar form of spacer 258 can be provided between top trim 210 of one panel 200 and bottom trim 220 of an adjacent panel 200, so that air circulation pathways 260 can be provided between each joint of adjacent but vertically spaced panels 200.

The stringers 190 extend substantially vertically so that the air circulation pathways extend substantially vertically up the slope of the roof R from the bottom vent 240 up through the top vent 250 to provide thorough cooling airflow beneath the series of panels 200. Alternatively, the stringers 190 could extend somewhat laterally, but not completely horizontally, and still achieve underlying support and allow for airflow beneath the panels 200. As another alternative, the stringers 190 could extend completely horizontally and appropriate relief holes could be formed in the stringers 190 to allow airflow to extend vertically along the pitch of the roof R and through such holes in the stringers 190.

Clips 270 are preferably provided mounted on the stringers 190 and adjacent a lowermost edge of the stringers 190 adjacent bottom trim 220 of lowermost panels 200 of the overall series of panels 200. These clips 270 are depicted in FIGS. 17-19. The clips are provided to hold down the bottom trim 220 and lower edge of the lowermost panel 200, such as to resist wind loads from causing a lowermost panel 200 to fly upward. The clip 270 also simultaneously accommodates some degree of thermal expansion and contraction between the stringers 190 and the panels 200.

Each clip 270 preferably includes a substantially planar plate 272 with an upper edge 274 spaced from a lower edge 276. The height of the clip 270 between the upper edge 274 and lower edge 276 is preferably slightly greater than a thickness of the stringers 190. The lower edge 276 is preferably aligned with a lower edge of the stringers 190 so that the upper edge 274 extends higher than an upper edge of the stringers 190 somewhat. A slot 278 is formed in the plate 272 slightly below the upper edge 274 and open at a bottom edge of the plate 272. The foot 228 of the bottom trim 220 of a lowermost one of the panels 200 can then slide into this slot 278 to hold the bottom trim 220 and lower edge of the panel 200 adjacent the stringer 190. The clip 270 is preferably fastened through holes therein to the stringer 190. As an alternative, the stringer 190 could be formed with the clips 270 provided as an integral portion of each stringer 190.

With particular reference to FIG. 26, details of lateral edge flashing 280 are described. Lateral edge flashing 280 is provided to integrate lateral edges of an array of the panels 200 into adjacent roofing R, such as shingles. In particular, the edge flashing 280 preferably includes a top plate 282 adapted to reside over a lateral edge of a panel 200, a bottom plate 284 adapted to reside upon a moisture barrier of the roof R, and a mid plate 286 joining the bottom plate 284 to the top plate 282. Shingles or other roofing materials are provided upon the bottom plate 284.

With the edge flashing 280 being substantially continuous between the top plate 282 and bottom plate 284, the ability of water to migrate laterally beneath the panels 200 from lateral edges thereof is precluded.

The panels 200 can be electrically coupled together the same as with the embodiment of FIGS. 1-14, with wiring merely routed as required underneath the panels 200.

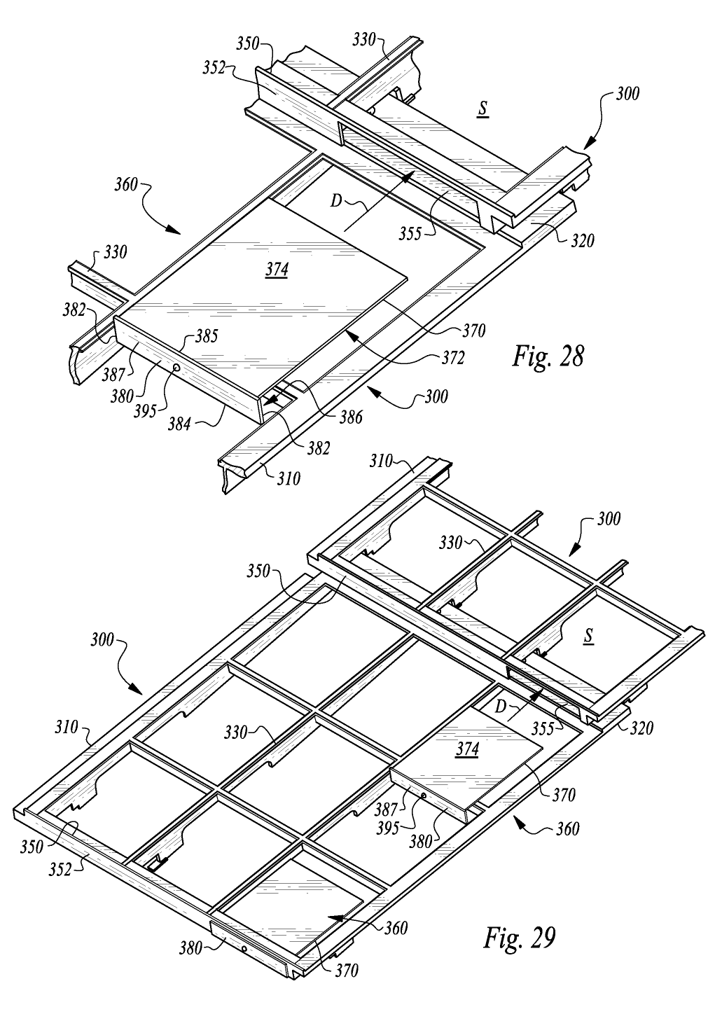

With particular reference to FIGS. 28-32, details of a further alternative embodiment panel 300 of this invention are described. In this further alternative panel 300, a variation on any of the above embodiments, or other embodiments of this invention is disclosed. In particular, in this embodiment the panel 300 is modified to feature a port 355 which is selectively openable and closable to provide access to photovoltaic cell electronics located within a space S beneath the photovoltaic cells 302 and within the cell support structure 330 which supports the cells 302 of the panel 300 above a roof R or other underlying surface.

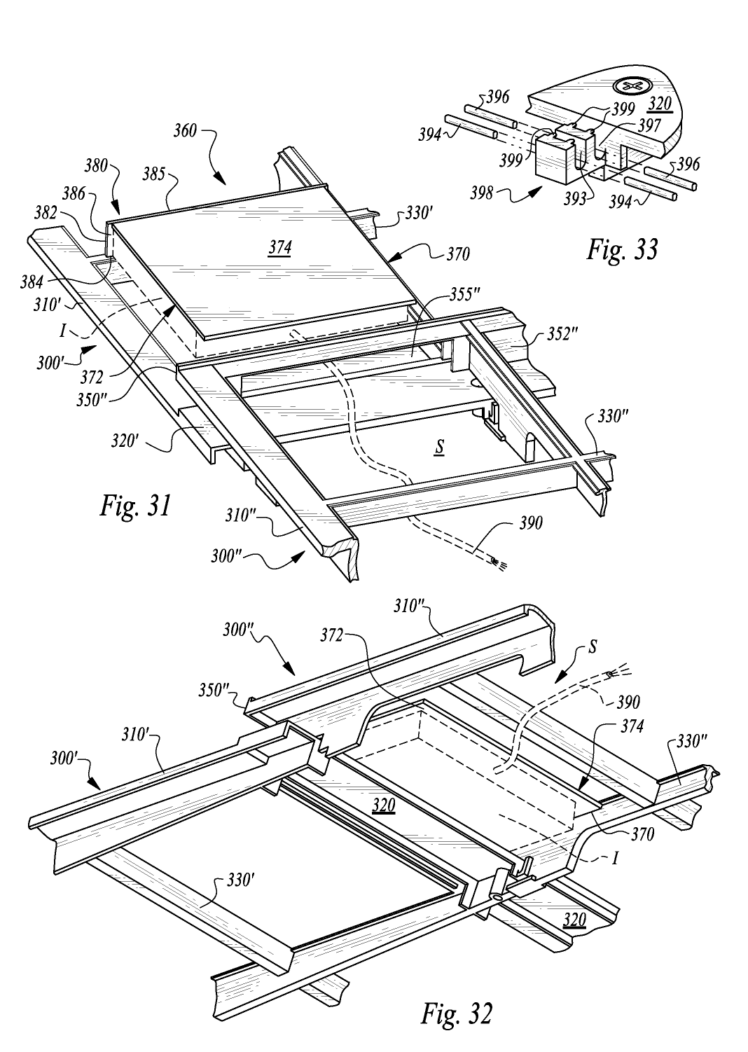

Photovoltaic cell 302 electronics I (FIGS. 31 and 32) can be a variety of different particular components or assemblies of components which support the function of the photovoltaic cells 302 and their interconnection together and within an overall power generation system. Examples of such photovoltaic cell electronics I include inverters, and particularly inverters of a type commonly referred to as “mini inverters,” “micro inverters” or “nano inverters.” Such devices can turn a single photovoltaic cell 302 or a small subset of local cells 302 within an overall array of photovoltaic cells 302 from the direct current electricity generated by the photovoltaic cells 302 themselves into alternating current, before being passed on to an alternating current power distribution system.

Other forms of photovoltaic cell electronics I could include elements such as the J-box 90 of previous embodiments, basic interconnection wiring for adjacent panels, sensing and monitoring equipment, control equipment, fuse boxes, and any other electronics associated with known photovoltaic panels 300 or photovoltaic cells 302 or photovoltaic panels and photovoltaic cells developed in the future which photovoltaic cell electronics I might benefit from access without requiring removal of the photovoltaic cells 302 or photovoltaic panels 300 from an overall array of such panels 300.

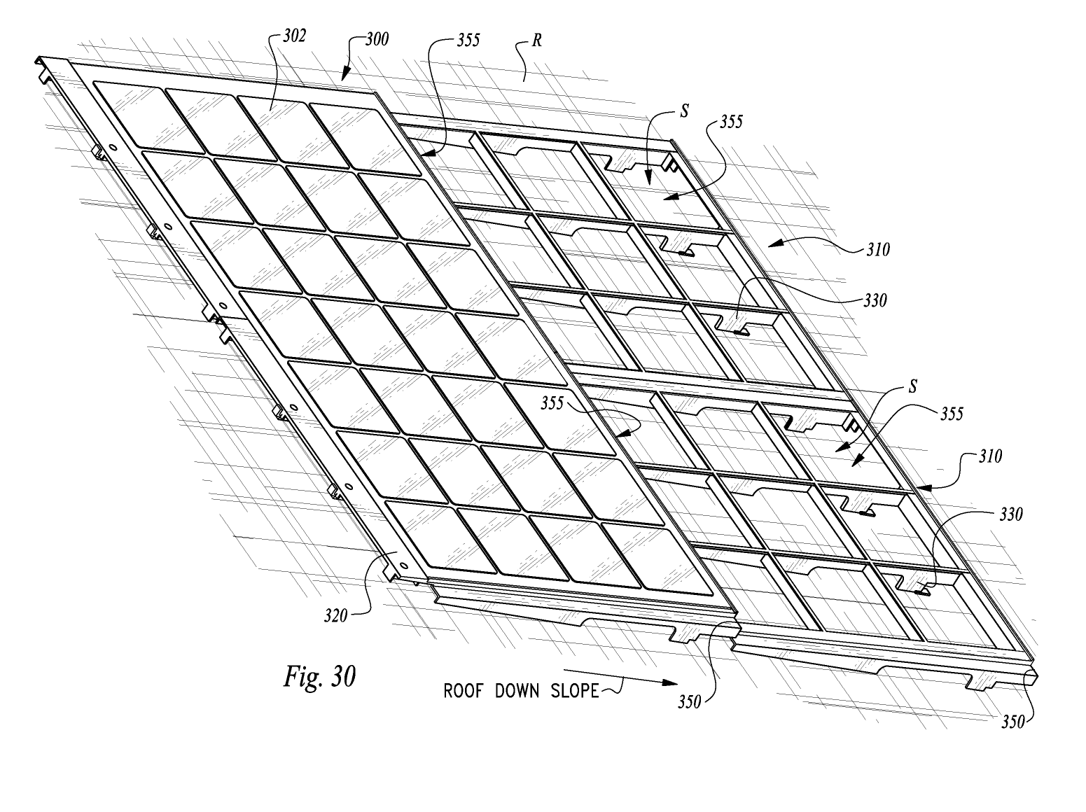

Preferably, the cell support structure 330 has multiple separate elements formed or bonded together and is provided by portions of brackets 310 which are each separately manufactured unitary rigid elements, such as might be formed by an injection molded plastic manufacturing process. In a preferred embodiment, two brackets 310 are provided for each panel 300 and underlying each single photovoltaic cell 302 (see FIG. 30). Preferably, a port 355 is provided within each of the brackets 310 so that a pair of ports 355 are provided within the cell support structure 330 of each panel 300. Thus, two separate locations are provided to support various different configurations for the locating of photovoltaic cell electronics I adjacent one of these ports 355 (or potentially adjacent both such ports 355).

The port 355 can have a variety of different shapes, but preferably is rectangular in form having a size and shape relative to other portions of the brackets 310 similar to that depicted in the figures (see FIGS. 28-30 in particular). As an alternative, other shapes for the port 355 could be provided.

The ports 355 are preferably located in a lower side wall 350 defining a portion of each bracket 310 opposite an upper side 320 which also preferably functions as a mounting rail. In this particular embodiment this lower side 350 is defined by a bottom trim surface 352. This bottom trim surface 352 is preferably planar and oriented substantially vertically (this angling of the bottom trim surface 352 varies somewhat as the roof R (FIG. 30) upon which the panel 300 is mounted varies in pitch.

A door 360 is preferably provided to selectively open and close the port 355. This door 360 can have a variety of different configurations, provided that it exhibits the basic function of being movable to transition between a more closed position and a more open position over the port 355. Most preferably, the door 360 can move to completely open the port 355 when in an open position and to completely close the port 355 when in a closed position.

In the preferred embodiment, the door 360 has a substantially planar tray portion 370 attached to a substantially perpendicular face portion 380. The tray portion 370 is configured to pass into the space S inboard of the port 355 and to have a substantially planar underside 372 opposite a substantially planar top side 374. The tray portion 370 thus extends substantially horizontally between an upper plane of the cell support structure 330 and a lower plane of the cell support structure 330 and above the space S within the cell support structure 330, where the photovoltaic cell electronics I can be located.

The face portion 380 is preferably substantially rectangular to overlie the port 355. This face portion 380 thus includes opposite lateral edges 382 extending between a bottom edge 384 and a top edge 385. The face portion 380 has an inner side 386 facing this space S and an outer side 387 opposite the inner side 386. This face portion is preferably planar and has dimensions slightly greater than that of the port 355 so that an inner side 386 of the face portion 380 at a perimeter thereof abuts an outer surface of the lower side wall 350 adjacent the port 355.

The tray portion 370 can extend from an upper edge of the face portion 380 or from the face portion 380 at a location slightly below the top edge 385 of the face portion 380. If desired, the outer side 387 can include some form of “pull” which can be grasped by a user to slide the door 360 out of the port 355 (along arrow D and opposite arrow D). The lower side wall 350 or other portions of the cell support structure 330 adjacent the port 355 can be configured with a form of “track” or other sliding support which can act with lateral side edges of the tray portion 370 of the door 360 or other portions of the door 360 to keep the door 360 generally aligned without rotation to slide smoothly along arrow D (FIGS. 28 and 30). Such a track can also provide sufficient friction to keep the door 360 from moving unless intentional forces are applied by a user to the door 360 to cause it to move. Detents or other latch features can also optionally be provided to securely hold the door 360 in a closed position when the door 360 is not intended to be moved.

While the photovoltaic cell electronics I can merely be placed within the space S and then accessed through the port 355 after opening of the door 360, a preferred embodiment has the photovoltaic cell electronics I at least partially mounted to the underside 372 of the tray portion 370 of the door 360. In this way, the door 360 can be slid out of the port 355 and the photovoltaic cell electronics I are simultaneously removed from the space S so that the photovoltaic cell electronics I can be directly accessed. Such access might be for inspection, maintenance, substitution of parts, or other service.

Wiring 390 preferably couples the photovoltaic cell electronics I to other portions of the photovoltaic cell 302. Such wiring 390 preferably has sufficient slack to allow the photovoltaic cell electronics to be slid out through the port 355 without disconnecting the wiring 390 between the photovoltaic cell electronics I and other portions of the cell 302. Preferably, readily operated interconnection plugs or other electrical connections are provided between the wiring 390 and the photovoltaic cell electronics I so that if replacement is required, such replacement can conveniently occur without requiring replacement of the wiring 390 or complex connection procedures.

The wiring 390, when extending between panels 310 and otherwise outside the panels 310 is preferably carried by support clips 398 extending from the mounting rails 320 (FIG. 33). These support clips 398 act as wire holders for the wiring 390. Each clip 398 preferably includes a pair of channels 393, 397 so that a primary wire 394 can be held separate from a secondary wire 396 without the wires 394, 396 being as susceptible to crimping or other damage when outside the panels 310. Wire 394, 396 management is thus facilitated.

Other optional details for the photovoltaic cell electronics I include provision of at least one hole 395 in the face portion 380 of the door 360 and inclusion on the photovoltaic cell electronics I of a light aligned with such a hole 395 (FIGS. 28 and 29). Such a light can function as a status light and be visible through the hole 395. For instance, with such indicator lights, and with such face portions 380 of the door 360 facing a ground area below a roof R installation for an array of panels 300, one could see such status lights. By providing a communication protocol associated with such an indicator light, the status of individual panels can be further evaluated, such as for trouble shooting and maintenance. For instance, a green light might indicate nominal performance, a red light might indicate that the panel is inoperative (or no light at all) and other colors of light might have other particular conditions associated therewith. Various sequences of blinking of a light of a single color or lights of different colors might further define an operational condition for the photovoltaic electronics and/or the cell 302 associated with the photovoltaic cell electronics. Multiple such holes 395 and/or lights could also be provided. A hole 395 could also allow for a diagnostic device to be plugged in through the hole and acquire data from the electronics I as to its condition, or acquire other useful information.

This disclosure is provided to reveal a preferred embodiment of the invention and a best mode for practicing the invention. Having thus described the invention in this way, it should be apparent that various different modifications can be made to the preferred embodiment without departing from the scope and spirit of this invention disclosure. When structures are identified as a means to perform a function, the identification is intended to include all structures which can perform the function specified. When structures of this invention are identified as being coupled together, such language should be interpreted broadly to include the structures being coupled directly together or coupled together through intervening structures. Such coupling could be permanent or temporary and either in a rigid fashion or in a fashion which allows pivoting, sliding or other relative motion while still providing some form of attachment, unless specifically restricted.

What is claimed is:

1. A roofing system with integrated photovoltaic power generation, comprising in combination:
a plurality of photovoltaic panels;
each photovoltaic panel including at least one photovoltaic cell on an upper surface thereof;
each photovoltaic panel including an underlying structure beneath said at least one photovoltaic cell;
said underlying structure including a lower side wall defining at least a portion of a lower edge of each said photovoltaic panel;
said underlying structure including an upper side opposite said lower side wall, said upper side defining at least a portion of an upper edge of each said photovoltaic panel;
said lower side wall of a first of said plurality of photovoltaic panels overlying said upper side of a second of said plurality of photovoltaic panels, with said first photovoltaic panel and said second photovoltaic panel adjacent each other and each angled with said upper sides higher than said lower side walls for each said photovoltaic panel;
said lower side wall of said first photovoltaic panel openly accessible above said at least one photovoltaic cell on said upper surface of said second photovoltaic panel underlying said first photovoltaic panel; and
at least one port in said lower side wall of said first photovoltaic panel, said port providing access to a space beneath said at least one photovoltaic cell of said first photovoltaic panel.

2. The system of claim 1 wherein said lower side wall of said first photovoltaic panel includes a plurality of ports therein.

3. The system of claim 2 wherein said underlying structure of said at least one photovoltaic panel includes multiple separate brackets with at least one port in each said lower side wall of each said bracket.

4. The system of claim 3 wherein at least one expansion joint is located between at least two of said multiple brackets of said first photovoltaic panel.

5. The system of claim 1 wherein said first photovoltaic panel includes a door, said door sized to cover said at least one port, said door movable between at least two positions with one of said at least two positions covering said port more completely than the other of said at least two positions.

6. The system of claim 5 wherein said door includes a face portion, said face portion being substantially planar and sized to overlie said port when said door is in a closed position.

7. The system of claim 6 wherein said face portion is sized larger than said port with a perimeter of said face portion adapted to abut at least portions of said lower side wall adjacent said port, and with portions of said door extending inward from said face and into said port.

8. The system of claim 6 wherein said door includes a tray portion extending from an inner side of said face portion, said tray portion extending through said port when said face portion is adjacent said lower side wall.

9. The system of claim 8 wherein said tray portion includes an underside having at least portions thereof above portions of said face portion of said door, such that at least portions of said underside of said tray portion overlie said space beneath said first photovoltaic panel, said tray portion adapted to have photovoltaic cell electronics coupled thereto through said underside of said tray portion, with said photovoltaic cell electronics coupled to said photovoltaic cell through wiring, said wiring having sufficient slack to allow said door to move away from said port in said lower side wall somewhat while remaining connected between said photovoltaic cell electronics and said photovoltaic cell.

10. A support structure for a photovoltaic cell to support the photovoltaic cell above an underlying angled surface along with a plurality of adjacent photovoltaic cells, the structure comprising in combination:
a plurality of elements extending between a lower plane adapted to abut the underlying angled surface and an upper plane adapted to abut and support the photovoltaic cell thereon;
a lower side wall defining at least a portion of a lower edge of the support structure and located between said lower plane and said upper plane;
an upper side opposite said lower side wall, said upper side defining at least a portion of an upper edge of the support structure and located between said lower plane and said upper plane;
space between said plurality of elements, between said upper plane and said lower plane, and between said lower side wall and said upper side, said space adapted to contain photovoltaic cell electronics therein; and
at least one port in said lower side wall, said port providing access to said space through said lower side wall.

11. The support structure of claim 10 wherein said lower side wall of said first photovoltaic panel includes a plurality of ports therein.

12. The support structure of claim 10 wherein said lower side wall is substantially planar.

13. The support structure of claim 12 wherein said port is wider horizontally than tall substantially vertically.

14. The support structure of claim 10 wherein said first photovoltaic panel includes a door, said door sized to cover said at least one port, said door movable between at least two positions with one of said at least two positions covering said port more completely than the other of said at least two positions.

15. The support structure of claim 14 wherein said door includes a face portion, said face portion being substantially planar and sized to overlie said port when said door is in a closed position.

16. The support structure of claim 15 wherein said face portion is sized larger than said port with a perimeter of said face portion adapted to abut at least portions of said lower side wall adjacent said port, and with portions of said door extending inward from said face and into said port.

17. The support structure of claim 15 wherein said door includes a tray portion extending from an inner side of said face portion, said tray portion extending through said port when said face portion is adjacent said lower side wall.

18. The support structure of claim 17 wherein said tray portion includes an underside having at least portions thereof above portions of said face portion of said door, such that at least portions of said underside of said tray portion, of said tray portion overlie said space beneath said first photovoltaic panel, said tray portion adapted to have photovoltaic cell electronics coupled thereto through said underside of said tray portion, with said photovoltaic cell electronics coupled to said photovoltaic cell through wiring, said wiring having sufficient slack to allow said door to move away from said port in said lower side wall somewhat while remaining connected between said photovoltaic cell electronics and said photovoltaic cell.

19. A method for accessing photovoltaic cell electronics of a partially stacked array of separate photovoltaic panels, with the array having a lower side wall defining at least a portion of a lower edge of a first photovoltaic panel overlying an upper side of a second photovoltaic panel, and with the first photovoltaic panel and the second photovoltaic panel adjacent each other and angled with the upper sides higher than the lower side walls for each of the photovoltaic panels, the accessing method including the steps of:
keeping the lower side wall of the first panel opening accessible above a photovoltaic cell on an upper surface of the second photovoltaic panel underlying the first photovoltaic panel;
identifying a port in the lower side wall, the port providing access to a space beneath a photovoltaic cell of the first photovoltaic panel; and
accessing photovoltaic cell electronics associated with the first photovoltaic panel which are located in the space beneath the photovoltaic cell of the first photovoltaic panel, through the port of said identifying step.

20. The method of claim 19 wherein said accessing step includes the further steps of:
identifying a door at least partially covering the port in the lower side wall; and
opening the door to more fully expose the port.

21. The method of claim 20 wherein said accessing step further includes:
mounting the photovoltaic cell electronics at least partially to portions of the door facing the space beneath the photovoltaic cell of the first photovoltaic panel; and
moving the door with the photovoltaic cell electronics at least partially mounted thereto at least partially out of the port for accessing the photovoltaic cell electronics.
